(19) United States
(12) Patent Application Publication
(10) Pub. No.: US 2007/0131159 A1
(43) Pub. Date: Jun. 14, 2007

(54) Method for epitaxial growth with selectivity

(76) Inventors: Young-Pil Kim, Suwon-si (KR); Jin Bum Kim, Seoul (KR); Min-Gu Kang, Seoul (KR); Yu-Gyun Shin, Seongnam-si (KR); Jong-Wook Lee, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 11/638,373

(22) Filed: Dec. 14, 2006

(30) Foreign Application Priority Data
Dec. 14, 2005 (KR) 2005-123314

(51) Int. Cl. C30B 13/00; C30B 19/00; C30B 28/08; C30B 23/00

(52) U.S. Cl. 117/58; 117/45; 117/105; 117/103; 117/92; 117/54

(57) ABSTRACT

A method for growing an epitaxial layer includes obtaining a semiconductor substrate having a plurality of insulating and conductive surfaces, adsorbing a first source gas into the plurality of conductive surfaces to grow a first epitaxial layer thereon, such that the first epitaxial layer has lateral portions overhanging the insulating surfaces, etching the first epitaxial layer to form an etched epitaxial layer, such that the etched epitaxial layer has curved surfaces, and supplying a second source gas to trigger additional epitaxial growth in the etched epitaxial layer.

### BACKGROUND OF THE INVENTION

1. Field of the Invention

The present invention relates to a method of forming a selective epitaxial growth in semiconductor devices. More particularly, the present invention relates to a method of forming a selective epitaxial growth having reduced width relative to its thickness.

2. Description of the Related Art

Selective epitaxial growth refers to a method of forming a thin crystalline layer on selected portions of a substrate. In the field of semiconductor devices, for example, portions of a silicon substrate may be exposed, such that a silicon crystalline layer may be grown on the exposed portions thereof. Such selective growth may provide a capability of varying doping concentration, forming elevated source/drain regions, or forming source/drain pads in a dynamic random access memory (DRAM).

In a conventional selective epitaxial growth method, a semiconductor substrate may be coated with a patterned insulation layer, such that portions of the substrate may be exposed through the patterned insulation layer to form a plurality of seed holes or conductive portions. A three-dimensional epitaxial layer portions may be grown in each of the seed holes or conductive portions of the substrate to form various patterns, e.g., layer portions having a plurality of facets and edges, having predetermined thickness and width values.

However, growing an epitaxial layer to a predetermined thickness may trigger overextended width thereof, i.e., lateral portions in a horizontal direction of each of the epitaxial layer portions may overhang the insulation layer. Extensive width of the epitaxial layer portions may result in bridging between facets and/or edges of adjacent lateral portions, thereby restricting further horizontal growth thereof. Limited horizontal growth may inhibit vertical growth, thereby resulting in epitaxial layers having insufficient overall thickness and uniformity.

Accordingly, there exists a need for a method for selectively forming an epitaxial layer on a semiconductor substrate having sufficient thickness.

### SUMMARY OF THE INVENTION

The present invention is therefore directed to a method for selectively growing epitaxial layers in semiconductor devices which substantially overcomes one or more of the disadvantages of the related art.

It is therefore a feature of an embodiment of the present invention to provide a method for selectively growing an epitaxial layer having a sufficient thickness by controlling a width thereof.

At least one of the above and other features and advantages of the present invention may be realized by providing a method for growing an epitaxial layer, including obtaining a semiconductor substrate having a plurality of insulating and conductive surfaces, adsorbing a first source gas into the plurality of conductive surfaces to grow a first epitaxial layer thereon, such that the first epitaxial layer may have lateral portions overhanging the insulating surfaces, etching the first epitaxial layer to form an etched epitaxial layer, such that the etched epitaxial layer may have curved surfaces, and supplying a second source gas to trigger additional epitaxial growth in the etched epitaxial layer. The adsorbing, etching, and supplying may be performed by an in-situ process.

Etching the first epitaxial layer may include employing an etching gas containing a hydrochloric acid gas (HCl). Etching the first epitaxial layer may also include employing an etching gas containing dichlorosilane (DCS), disilane (Si₂H₆), silane (SiH₄), or germane (GeH₄) in an amount of about 5% to about 15% by volume of the etching gas.

Adsorbing and supplying the source gas may include employing dichlorosilane (DCS), disilane (Si₂H₆), silane (SiH₄), or germane (GeH₄). Adsorbing and supplying the source gas may also include use of hydrochloric acid gas (HCl). The first and second source gases may be the same.

Adsorbing a first source gas into the plurality of conductive surfaces to grow a first epitaxial layer may include forming a plurality of epitaxial layer portions, each epitaxial layer portion having lateral portions overhanging the insulating surfaces. Additionally, etching the first epitaxial layer may further include reducing a width of each epitaxial layer portion, such that a thickness to width ratio of each epitaxial layer portion is reduced as compared to a thickness to width ratio of an un-etched epitaxial layer portion.

In another aspect of the present invention, there is provided a method for preparing epitaxial layers, including applying an insulating layer to a semiconductor substrate, such that a plurality of active regions at a predetermined angle may be formed therein, disposing a plurality of gate patterns on the insulating layer, such that the gate patterns may intersect with the plurality of active regions, adsorbing a first source gas into the plurality of active regions to grow a first epitaxial layer thereon, such that the first epitaxial layer may have lateral portions overhanging the insulating layer, etching the first epitaxial layer to form an etched epitaxial layer, such that the etched epitaxial layer may have curved surfaces, and supplying a second source gas to trigger additional epitaxial growth in the etched epitaxial layer. The epitaxial layer may be formed to fill a gap between adjacent gate patterns. The adsorbing, etching, and supplying may be performed by an in-situ process.

Etching the first epitaxial layer may include employing an etching gas containing a hydrochloric acid gas (HCl). Etching the first epitaxial layer may also include employing an etching gas containing dichlorosilane (DCS), disilane (Si₂H₆), silane (SiH₄), or germane (GeH₄) in an amount of about 5% to about 15% by volume of the etching gas.

Adsorbing and supplying the source gas may include employing dichlorosilane (DCS), disilane (Si₂H₆), silane (SiH₄), or germane (GeH₄). Adsorbing and supplying the source gas may also include use of hydrochloric acid gas (HCl). The first and second source gases may be the same.

Disposing a plurality of gate patterns may include intersecting each active region with two gate patterns. Intersecting each active region with two gate patterns may include forming two electrode gates and three active portions, such that the each electrode gate is disposed between two active portions. Additionally, adsorbing the first source gas into the plurality of active regions may include growing a first epitaxial layer on the three active portions.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a partial plane view of a semiconductor device in accordance with an embodiment of the present invention;

FIG. 2 illustrates a flow chart of a method of preparing an epitaxial layer in accordance with an embodiment of the present invention; and

FIGS. 3-5 illustrate sequential sectional views corresponding to processing steps of the method illustrated in FIG. 2.

### DETAILED DESCRIPTION OF THE INVENTION

Korean Patent Application 2005-123314 filed on Dec. 14, 2005, in the Korean Intellectual Property Office, and entitled: “Method for Epitaxial Growth with Selectivity,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

It will further be understood that when an element or layer is referred to as being “on” another element, layer or substrate, it can be directly on the other element, layer or substrate, or intervening elements/layers may also be present. Further, it will be understood that when an element or layer is referred to as being “under” another element or layer, it can be directly under, or one or more intervening elements or layers may also be present. In addition, it will also be understood that when an element or layer is referred to as being “between” two elements or layer, it can be the only element or layer between the two elements or layers, or one or more intervening elements or layers may also be present. Like reference numerals refer to like elements throughout.

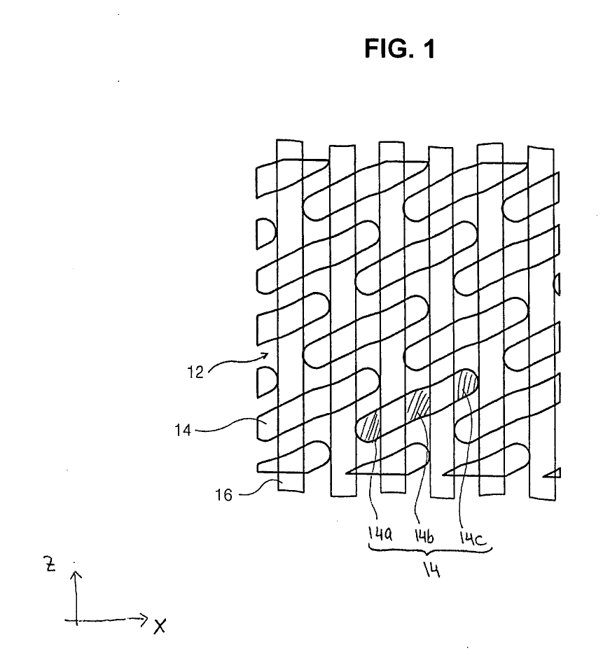

An exemplary embodiment of a semiconductor device according to the present invention is more fully described below with reference to FIG. 1. As illustrated in FIG. 1, a semiconductor device, e.g., a DRAM, in accordance with an embodiment of the present invention may include a substrate (not shown), an insulation layer 12 formed on the substrate, a plurality of active regions 14, and a plurality of gate patterns 16.

The insulation layer 12 may be a patterned insulating film, such that a plurality of gaps may be formed therein to define the plurality of active regions 14. The plurality of active regions 14 may be in communication with the substrate and arranged in various patterns to provide a higher integration degree. For example, the plurality of active regions 14 may be formed as a plurality of sequential discontinuous segments arranged in parallel rows and at a predetermined angle, as illustrated in FIG. 1. With respect to the present invention “a predetermined angle” refers to any angle other than 0° or 90° formed between the active regions 14 and an x-axis, as illustrated in FIG. 1.

Each gate pattern 16 may include a gate insulation film (not shown), at least one gate electrode (not shown) having sidewalls and formed on the gate insulation film, spacers (not shown) disposed on the sidewalls of the gate electrode, and a capping insulation film (not shown) disposed on the gate electrode. The at least one gate electrode may intersect with the active region 14.

In particular, the plurality of gate patterns 16 may be formed in a stripe pattern on the substrate, such that a plurality of longitudinal members may be disposed in parallel and at equal intervals on the substrate. More specifically, the insulation layer 12 and the active regions 14 may be disposed between the substrate and the plurality of gate patterns 16, such that each active region 14 may intersect with two gate patterns 16, i.e., each active region 14 may have two intersection regions with the gate patterns 16. The two intersection regions of the active regions 14 may divide each active region 14 into a first, second, and third active portion 14a, 14b, and 14c, respectively, each portion separated from the other portion by the intersection region, as illustrated in FIG. 1. Each intersection region may include the gate electrode of a respective gate pattern 16.

The three active portions 14a, 14b and 14c may be treated to operate as source and drain regions. In particular, the substrate may be treated with ionic impurities at predetermined regions, such that the second active portion 14b of each active region 14 may be a drain region and the first and third active portions 14a and 14c of each active region 14 may be source regions. More specifically, as illustrated in FIG. 1, the drain region, i.e., the second active portion 14b, may be formed in a center of the active region 14 between two gate electrodes of the gate pattern 16, and the source regions, i.e., the first and third active portions 14a and 14c, may be formed in peripheral portions of the active region 14. Accordingly, each gate electrode of the gate pattern 16 may be positioned between one drain region and one source region.

An epitaxial layer according to an embodiment of the present invention may be selectively formed on the source and drain regions, i.e., first, second and third active portions 14a, 14b and 14c, respectively, of the active region 14. The epitaxial layer may form, for example, elevated source/drain regions or source/drain pads for connecting the source/drain regions with contact plugs to be formed later. In this respect, it should be noted that the epitaxial layer may be isolated from the gate electrodes of the gate patterns 16 by the spacers thereof. Alternatively, the epitaxial layers may be formed on the gate electrodes of the gate patterns 16.

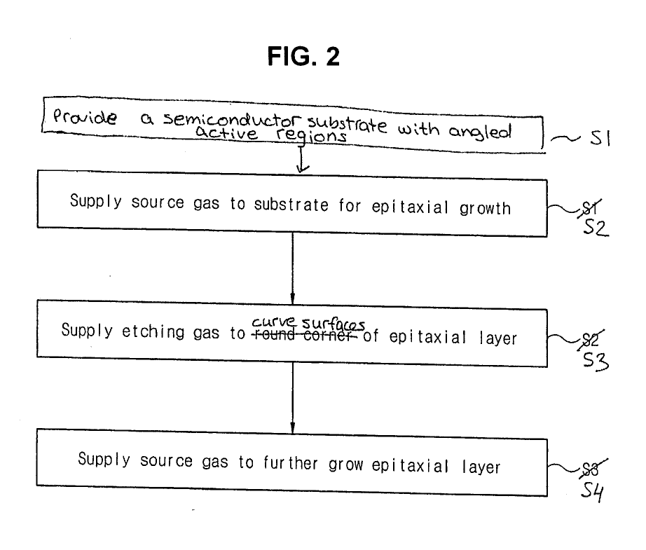

According to another aspect of the present invention, an exemplary method of forming a selective epitaxial layer according to an embodiment of the present invention will be more fully described with respect to FIGS. 2-5.

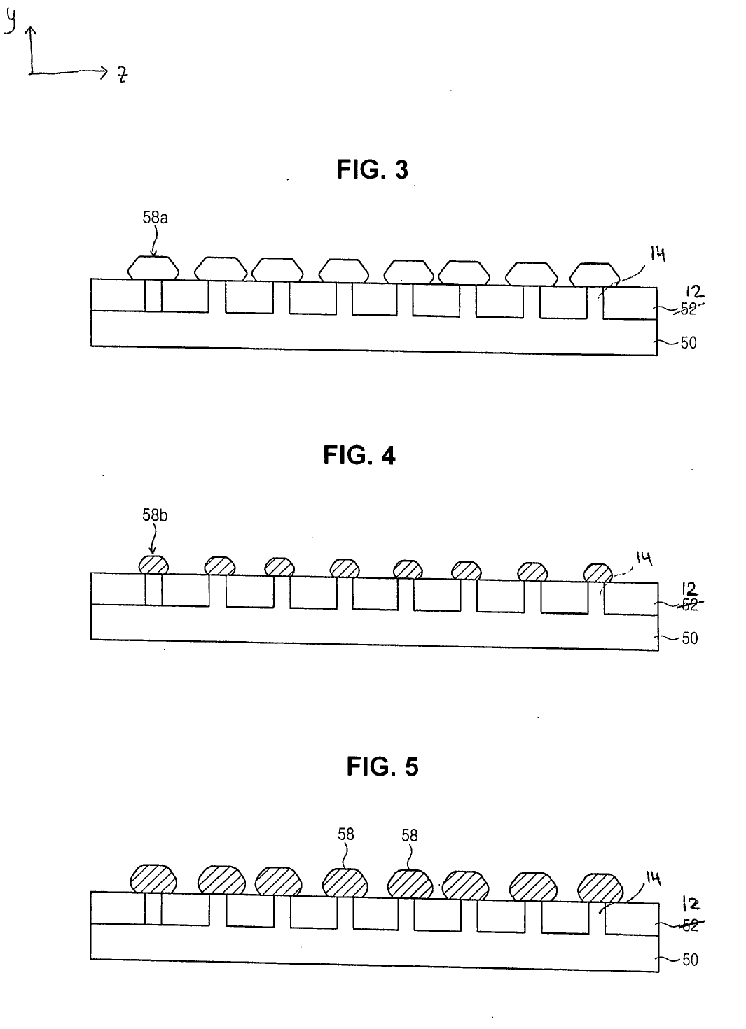

First, i.e., in step S1, a semiconductor substrate 50 may be coated with the insulation layer 12, such that the active regions 14 may be defined therein, as illustrated in FIGS. 1 and 3. In particular, the insulation layer 12 may be formed such that the active regions 14 may be defined at a predetermined angle. Next, gate patterns 16 may be disposed on the semiconductor substrate 50 as previously described with respect to FIG. 1. Subsequently, the semiconductor substrate 50 may be placed inside a temperature-controlled reaction chamber, where epitaxial layer portions 58a may be grown thereon. In this respect, it should be noted that “epitaxial layer portions” refer to discrete portions grown on separate active regions 14 or portions thereof of the semiconductor substrate 50. On the other hand, an “epitaxial layer” refers cumulatively to a plurality of epitaxial layer portions formed on a semiconductor substrate.

Without intending to be bound by theory, it is believed that formation of the insulation layer 12 and the active regions 14 according to an embodiment of the present invention illustrated in FIGS. 1 and 3, i.e., formation of the active regions 14 at the predetermined angle may be advantageous in preventing bridging between adjacent facets and/or edges of the epitaxial layer portions 58a. In particular, the geometric configuration of the active regions 14 illustrated in FIG. 1 may trigger different growth rates thereon with respect to the crystalline orientation of the semiconductor substrate 50, such that adjacent epitaxial layer portions 58a disposed on a, same active region 14 may have different thickness and width values. As a result, adjacent epitaxial layer portions 58a may have different structures and increased gaps therebetween, thereby exhibiting minimized contact between facets and/or edges thereof.

In more detail, growth of the epitaxial layer portions 58a may first include supplying a source gas into a reaction chamber having the semiconductor substrate 50, i.e., step S2, as illustrated in FIG. 2. The source gas may be any precursor gas containing silicon or germanium, e.g., dichlorosilane (DCS), disilane (Si₂H₆), silane (SiH₄), germane (GeH₄), and so forth, to trigger growth of a silicon or germanium epitaxial layer. Additionally, small amounts of chlorine containing gas, e.g., hydrochloric acid gas (HCl), may be added to the source gas to limit formation of an epitaxial layer on the insulation layer 12, i.e., interaction of the HCL gas with an oxide or nitride film employed as the insulation layer 12 may inhibit adsorption of the source gas therein, thereby minimizing growth of an epitaxial layer in the insulation layer 12.

The source gas may dissociate in the reaction chamber as a result of the temperature therein, thereby triggering silicon or germanium adsorption into the active regions 14 of the semiconductor substrate 50 and facilitating growth of the epitaxial layer portions 58a therein. The growth of the epitaxial layer portions 58a may be monitored to achieve a predetermined thickness thereof, as measured in a vertical direction, i.e., along a y-axis. In this respect, it should be noted that the growth rate of the epitaxial layer portions 58a may depend on a crystalline orientation thereof, such that the epitaxial layer portions 58a may grow to have three-dimensional crystalline structures having a plurality of surfaces and boundaries capable of filling gaps or spaces between the gate patterns 16 and, subsequently, extending laterally, i.e., along a horizontal direction along a z-axis, as illustrated in FIGS. 3-5, to overhang the insulation layer 12.

Next, in step S3, the supply of the source gas may be paused, and an etching gas may be supplied to etch the epitaxial layers 58a, as illustrated in FIG. 2. In particular, the etching gas may be any etching gas employed in the art in similar processes, e.g., wet etching process, and having an etch selectivity with respect to silicon and germanium. The etching gas may include HCl gas with a small amount, e.g., from about 2% to about 10% by volume of the total etching gas, of DCS, Si₂H₆, SiH₄, or GeH₄ in order to enhance the etch rate.

The etching gas may etch the edges of the epitaxial layer portions 58a to form etched epitaxial layer portions 58b having curved surfaces, as illustrated in FIG. 4. In other words, the etching gas may round the edges of each epitaxial layer portions 58a and minimize the width thereof, i.e., as measured along the z-axis, such that a horizontal distance between adjacent etched epitaxial layer portions 58b along the z-axis may be maximized, while contact therebetween may be minimized. Accordingly, the width of the etched epitaxial layer portions 58b may be significantly reduced, such that a thickness/width ratio of each etched epitaxial layer portion 58b may be increased as compared to a thickness/width ratio of each epitaxial layer portion 58a, i.e., thickness/width ratio prior to etching.

Once the edges of the etched epitaxial layer portions 58b are etched to have curved surfaces, the etching gas may be paused and the source gas may be supplied again into the reaction chamber in step S4. In particular, the source gas may dissociate again in the reaction chamber and trigger further silicon and/or germanium adsorption into the active regions 14, thereby advancing further epitaxial growth of etched epitaxial layer portions 58b. The etched epitaxial layer portions 58b may grow into three-dimensional epitaxial layers 58. Without intending to be bound by theory, it is believed that because the etched epitaxial layer portions 58b may be formed to have curved surfaces with reduced width in step S3, the etched epitaxial layer portions 58 in step S4 may continue growing vertically and horizontally according to the crystalline orientation thereof without horizontal bridging therebetween. In particular, because the thickness/width ratio of the etched epitaxial layer portions 58b is smaller as compared to the thickness/width ratio of the epitaxial layer portions 58a, the etched epitaxial layer portions 58b may grow vertically into epitaxial layers 58 and achieve a desired thickness without intersecting horizontally with adjacent etched epitaxial layer portions 58b.

Steps S1 through S3 may be performed by an in-situ process, i.e., varying the supply time and components of the source and etching gases into the reaction chamber without removing the semiconductor substrate from the reaction chamber. Further, the epitaxial layers 58 may contain different layers, e.g., a first epitaxial layer and a second epitaxial layer may include alternating layers of silicon and germanium epitaxial layers.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method for growing an epitaxial layer, comprising:
providing a semiconductor substrate having a plurality of insulating and conductive surfaces;
adsorbing a first source gas into the plurality of conductive surfaces to grow a first epitaxial layer thereon, such that the first epitaxial layer has lateral portions overhanging the insulating surfaces;
etching the first epitaxial layer to form an etched epitaxial layer, such that the etched epitaxial layer has curved surfaces; and
supplying a second source gas to trigger additional epitaxial growth in the etched epitaxial layer.

2. The method as claimed in claim 1, wherein adsorbing, etching, and supplying are performed by an in-situ process.

3. The method as claimed in claim 1, wherein etching the first epitaxial layer includes employing an etching gas containing a hydrochloric acid gas (HCl).

4. The method as claimed in claim 3, wherein etching the first epitaxial layer includes employing an etching gas further containing dichlorosilane (DCS), disilane (Si₂H₆), silane (SiH₄), or germane (GeH₄).

5. The method as claimed in claim 4, wherein the etching gas includes dichlorosilane (DCS), disilane (Si₂H₆), silane (SiH₄), or germane (GeH₄) in an amount of about 5% to about 15% by volume of the etching gas.

6. The method as claimed in claim 1, wherein adsorbing the first gas and supplying the second source gas includes employing dichlorosilane (DCS), disilane (Si₂H₆), silane (SiH₄), or germane (GeH₄).

7. The method as claimed in claim 6, wherein wherein adsorbing the first gas and supplying the second source gas further included employing hydrochloric acid gas (HCl).

8. The method as claimed in claim 1, wherein the first source gas and the second source gas are the same.

9. The method as claimed in claim 1, wherein adsorbing a first source gas into the plurality of conductive surfaces to grow a first epitaxial layer includes forming a plurality of epitaxial layer portions, each epitaxial layer portion having lateral portions overhanging the insulating surfaces.

10. The method as claimed in claim 9, wherein etching the first epitaxial layer further comprises reducing a width of each epitaxial layer portion, such that a thickness to width ratio of each etched epitaxial layer portion is reduced as compared to a thickness to width ratio of an unetched epitaxial layer portion.

11. A method for preparing epitaxial layers, comprising:
applying an insulating layer to a semiconductor substrate, such that a plurality of active regions at a predetermined angle is formed therein;
disposing a plurality of gate patterns on the insulating layer, such that the gate patterns intersect with the plurality of active regions;
adsorbing a first source gas into the plurality of active regions to grow a first epitaxial layer thereon, such that the first epitaxial layer has lateral portions overhanging the insulating layer;
etching the first epitaxial layer to form an etched epitaxial layer, such that the etched epitaxial layer has curved surfaces; and
supplying a second source gas to trigger additional epitaxial growth in the etched epitaxial layer.

12. The method as claimed in claim 11, wherein adsorbing, etching, and supplying are performed by an in-situ process.

13. The method as claimed in claim 11, wherein etching the first epitaxial layer comprises employing an etching gas containing a hydrochloric acid gas (HCl).

14. The method as claimed in claim 13, wherein etching the first epitaxial layer comprises employing an etching gas further containing dichlorosilane (DCS), disilane (Si₂H₆), silane (SiH₄), or germane (GeH₄) in an amount of about 5% to about 15% by volume of the etching gas.

15. The method as claimed in claim 11, wherein adsorbing and supplying the source gas comprises employing dichlorosilane (DCS), disilane (Si₂H₆), silane (SiH₄), germane (GeH₄),

16. The method as claimed in claim 15, wherein adsorbing and supplying the source gas may further include use of hydrochloric acid gas (HCl).

17. The method as claimed in claim 11, wherein the epitaxial layer is formed to fill a gap between adjacent gate patterns.

18. The method as claimed in claim 11, wherein disposing a plurality of gate patterns includes intersecting each active region with two gate patterns.

19. The method as claimed in claim 18, wherein intersecting each active region with two gate patterns comprises forming two electrode gates and three active portions, such that the each electrode gate is disposed between two active portions.

20. The method as claimed in claim 19, wherein adsorbing the first source gas into the plurality of active regions comprises growing a first epitaxial layer on the three active portions.
